(19) United States
(12) Patent Application Publication
(10) Pub. No.: US 2012/0039022 A1
(43) Pub. Date: Feb. 16, 2012

(54) Electrically Insulated Water Meter

(76) Inventors: Cruz CAMPOS, JR., Lancaster, CA (US); Desley ONEAL, Lake View Terrace, CA (US)

(21) Appl. No.: 12/855,990

(22) Filed: Aug. 13, 2010

(51) Int. Cl. H05K 7/00

(52) U.S. Cl. 361/679.01

(57) ABSTRACT

An electrically insulated water meter prevents electrical current from flowing between in-house plumbing and a water main. Known water meters are connected to water mains and to in-house plumbing through metal couplings and metal pipes. The metal pipes, metal couplings, and a metal water meter housing complete an electrical circuit allowing the flow of electrical current. Such electrical current causes water mains and services to corrode and deteriorate thus shortening their life span by causing leaks and breaks, and is also a health risk for water company employees who risk electrical shocks due to the electrical current. The electrically insulated water meter includes non-conducting couplings between the water meter housing and the water pipes connected to the water meter housing, to prevent the flow of electrical current. Including the non-conducting couplings on both sides of the water meter housing prevents the electrical shocks to the water company employees.

### BACKGROUND OF THE INVENTION

The present invention relates to water meters and in particular to a water meter electrically insulated from water pipes carrying water to and from the water meter.

Known water meters are connected to both waters mains and to building using standard metal couplings and associated metal water pipes, thereby providing a conducting path for electrical current. Such electric current (plumbing current) is often present in such water pipes as a result of grounding and wiring problems, or through ground current as the electricity makes its way back to the substation via the ground. Many homes today are now affected by plumbing current. For example, some of the current which would normally return through the electrical service line is instead channeled into the grounding system, where it returns to the transformer by way of alternate paths, including water pipes, the public water main and neighboring residences. Galvanic action may be an additional source of such electrical current.

Unfortunately, such plumbing current causes water mains and services to corrode and deteriorate thus shortening their life span and causing leaks and breaks. Electricity in the system is also a health risk for water company employees who tend to frequently be exposed to electrical shocks. No solutions are presently available to address this issues and a solution is needed.

### BRIEF SUMMARY OF THE INVENTION

The present invention addresses the above and other needs by providing an electrically insulated water meter which prevents electrical current from flowing between in-house plumbing and a water main. Known water meters are connected to water mains and to in-house plumbing through metal couplings and metal pipes. The metal pipes, metal couplings, and a metal water meter housing complete an electrical circuit allowing the flow of electrical current. Such electrical current causes water mains and services to corrode and deteriorate thus shortening their life span by causing leaks and breaks, and is also a health risk for water company employees who risk electrical shocks due to the electrical current. The electrically insulated water meter includes non-conducting couplings between the water meter housing and the water pipes connected to the water meter housing, to prevent the flow of electrical current. Including the non-conducting couplings on both sides of the water meter housing prevents the electrical shocks to the water company employees.

In accordance with one aspect of the invention, there are provided electrically insulating couplings between a water meter housing and pipes connected to both a water main and in-house plumbing.

In accordance with another aspect of the invention, there is provided an electrically isolated water meter. The electrically isolated water meter includes a water meter housing made of an electrically conductive material, an electrically conductive first pipe in fluid communication with an inlet of the water meter housing, a first coupling connecting the first pipe to the water meter housing, an electrically conductive second pipe in fluid communication with an outlet of the water meter housing, and a second coupling connecting the second pipe to the water meter housing. At least one of the first coupling and the second coupling electrically isolate the water meter housing from the first pipe and the second pipe respectively, and preferably both the first coupling and the second coupling electrically isolate the water meter housing from the first pipe and the second pipe respectively.

### BRIEF DESCRIPTION OF THE SEVERAL VIEWS OF THE DRAWING

The above and other aspects, features and advantages of the present invention will be more apparent from the following more particular description thereof, presented in conjunction with the following drawings wherein:

FIG. 1A is a side view of an electrically insulated water meter according to the present invention.

FIG. 1B is a top view of the electrically insulated water meter according to the present invention.

FIG. 2 is a cross-sectional view of an electrically insulating coupling according to the present invention coupling a first pipe to the water meter taken along line 2-2 of FIG. 1B.

FIG. 3A is an end view of a nut element of the electrically insulating coupling according to the present invention.

FIG. 3B is a side view of the nut element of the electrically insulating coupling according to the present invention.

FIG. 4 is a cross-sectional view of the nut element of the electrically insulating coupling according to the present invention taken along line 4-4 of FIG. 3A.

FIG. 5 is an end view of a wash element of the electrically insulating coupling according to the present invention.

FIG. 6 is a cross-sectional view of the washer element of the electrically insulating coupling according to the present invention taken along line 6-6 of FIG. 5.

Corresponding reference characters indicate corresponding components throughout the several views of the drawings.

### DETAILED DESCRIPTION OF THE INVENTION

The following description is of the best mode presently contemplated for carrying out the invention. This description is not to be taken in a limiting sense, but is made merely for the purpose of describing one or more preferred embodiments of the invention. The scope of the invention should be determined with reference to the claims.

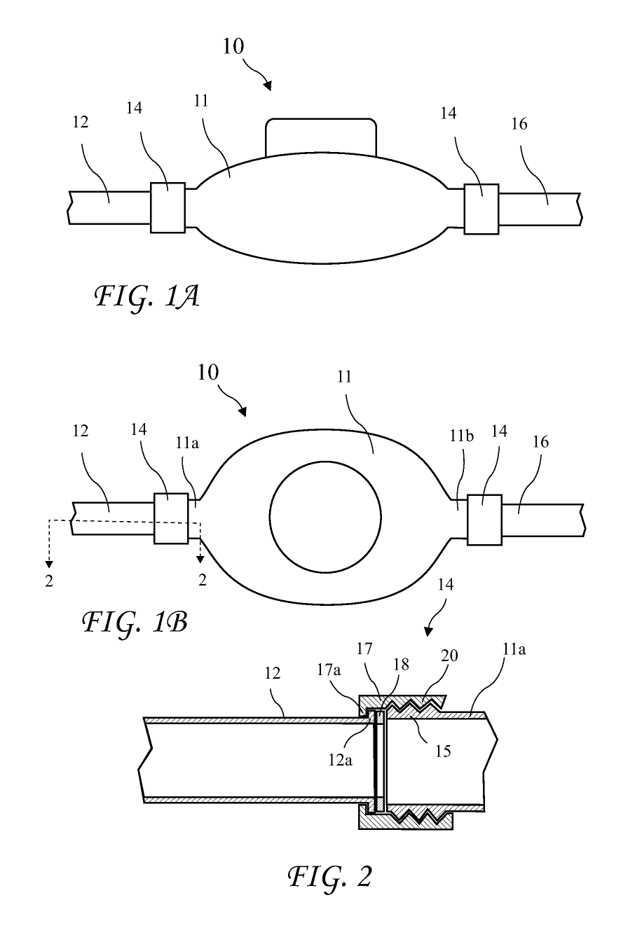

A side view of an electrically insulated water meter 10 according to the present invention is shown in FIG. 1A and a top view of the electrically insulated water meter 10 is shown in FIG. 1B. The water meters have a conductive housing 11 and plumbing current may be conducted from a first pipe 12, through the conductive housing 11, and to a second pipe 16, if the pipes 12 and 16 are coupled to the housing 11 by conducting material. Such plumbing current causes water mains and services to corrode and deteriorate thus shortening their life span and causing leaks and breaks, and is also a health risk for water company employees who tend to frequently be exposed to electrical shocks.

A cross-sectional view of the electrically insulating coupling 14 according to the present invention, taken along line 2-2 of FIG. 1B, is shown in FIG. 2. The couplings 14 include a nut 17 and a washer 18. Both the nut 17 and the washer 18 are made from non-electrically conducting material. The non-electrically conducting couplings 14 electrically insulating the pipes 12 and 16 from the housing 11 thereby eliminating the plumbing current.

The nuts 17 include female threads 20 cooperating with male threads 15 on an inlet 11a and outlet 11b of the housing 11. The pipes 12 and 16 include flairs, for example, a flair 12a on the pipe 12, cooperating with flanges 17a on the nuts 17 to hold the pipes 12 and 16 to the housing 11. The washers 18 separate the ends of the pipes 12 and 16 from the inlet 11a and outlet 11b of the housing 11.

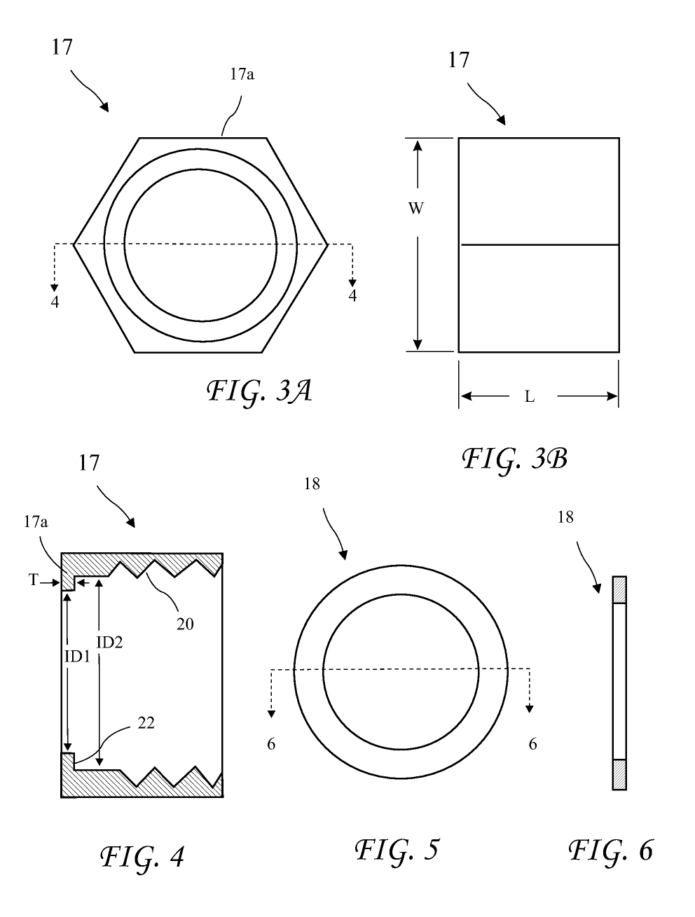

An end view of the nut 17 of the electrically insulating coupling 14 is shown in FIG. 3A, side view of the nut 17 is shown in FIG. 3A, and a cross-sectional view of the nut 17 taken along line 4-4 of FIG. 3A is shown in FIG. 4. The nut 14 includes a hexagonal outer shape 14a for cooperation with a tool for tightening the nut 14, but may have any shape suitable for cooperation with a matching tool.

The washer 18 seats inside the nut 17 against the flange 17a in an area having a second inside diameter ID2 and the pipes 12 and 16 enter the nut 17 through a passage having a first inside diameter ID1. An example of a suitable nut 17 has a length L of approximately 15/16 inches, a width W of approximately 1 and ⅞ inches, the first inside diameter ID1 of approximately 1 and 1/16 inches, a second inside diameter ID2 of approximately 1 and 5/16 inches, and a flange 17a having a thickness T of approximately ⅛ inches.

The above dimensions are one example. Water meters are made in various sizes depending on the water service provided, and the specifications of male threads on water meters are generally referred to as Water Meter Threads (WMT) and are commonly ¾ inch, one inch, 1 and ¼ inch, and 1 and ½ inch WMTs. Any water meter including electrically insulating couplings and having any thread size is intended to come within the scope of the present invention.

An end view of the washer 18 according to the present invention is shown in FIG. 5 and a cross-sectional view of the washer 18 taken along line 6-6 of FIG. 5 is shown in FIG. 6. The washer 18 has an outside diameter suitable for seating in the nut 17 against the flare 12a (see FIG. 2) of the pipe 12 to separate the flair 12a from the end of the inlet 11a providing electrical insulation.

Known water meters are made by Badger, Neptune, Sensus and Rockwell, which are all compatible with the nut according to the present invention. While these are common water meters, any water meter installed to be electrically insulated from water pipes is intended to come within the scope of the present invention.

The coupling 14, generally the nut 17 and washer 18, must be made of an electrically insulating material with suitable mechanical properties to mechanically couple the pipes to the water meter, and the nut must additionally have sufficient mechanical strength to hold the pipes against the water meter housing. Examples of suitable materials for making the nut 17 include ABS, Styrene, Nylon, Polyester, Polycarbonate, Noryl, and Xenoy. The washer 18 is in compression and does not require the mechanical strength of the nut 17 but must also be an electrical insulator. An example of a suitable material for the washer is neoprene, rubber, leather or fiber.

While the invention herein disclosed has been described by means of specific embodiments and applications thereof, numerous modifications and variations could be made thereto by those skilled in the art without departing from the scope of the invention set forth in the claims.

I claim:

1. An electrically isolated water meter comprising:
a water meter housing made of an electrically conductive material;
an electrically conductive first pipe in fluid communication with an inlet of the water meter housing, the first pipe receiving water from a water main;
a first coupling connecting the first pipe to the water meter housing;
an electrically conductive second pipe in fluid communication with an outlet of the water meter housing, the second pipe providing the water to a building; and
a second coupling connecting the second pipe to the water meter housing,
wherein one of the first coupling and the second coupling electrically isolates the water meter housing from one of the first pipe and the second pipe respectively.

2. The electrically isolated water meter of claim 1, wherein both the first coupling and the second coupling electrically isolate the water meter housing from the first pipe and the second pipe respectively.

3. The electrically isolated water meter of claim 2, wherein:
the first coupling and the second coupling comprise a nut residing on the end of the first pipe and the second pipe respectively, the nuts made from a non-electrically conductive material and threaded into the water meter housing to attach the first pipe and the second pipe to the water meter housing.

4. The electrically isolated water meter of claim 3, further including gaskets sandwiched between ends of the first pipe and the second pipe and the water meter housing, the gaskets made of a non-electrically conductive material.

5. The electrically isolated water meter of claim 4, wherein:
the inlet and outlet of the water meter housing include male threads;
the nuts have an open end having female threads for cooperation with the male threads securing the nuts to the inlet and the outlet;
the nuts have a partially closed ends opposite the open ends;
the pipes include a flange residing inside the nuts and cooperating with the partially closed ends to retain the nuts on the pipes; and
the gaskets reside between the flanges and the water meter housing to electrically isolate the water meter housing from the first pipe and the second pipe.

6. The electrically isolated water meter of claim 1, wherein:
one of the inlet and outlet of the water meter housing includes male threads;
one of the couplings comprises:
a nut having an open end having female threads for cooperation with the male threads securing the nut to one of the inlet and the outlet;
the nut has a partially closed end opposite the open end;
a corresponding one of the pipes includes a flange residing inside the nut and cooperating with the partially closed end to retain the nut on the pipe; and
the gaskets reside between the flanges and the water meter housing to electrically isolate the water meter housing from the first pipe and the second pipe.

7. An electrically isolated water meter comprising:
a water meter housing made of an electrically conductive material;
an electrically conductive first pipe in fluid communication with an inlet of the water meter housing, the first pipe receiving water from a water main;
a first coupling connecting the first pipe to the water meter housing;
an electrically conductive second pipe in fluid communication with an outlet of the water meter housing, the second pipe providing the water to a building; and
a second coupling connecting the second pipe to the water meter housing,
wherein the first coupling and the second coupling electrically isolate the water meter housing from the first pipe and the second pipe respectively.

8. An electrically isolated water meter comprising:
a water meter housing made of an electrically conductive material;
an electrically conductive first pipe in fluid communication with an inlet of the water meter housing, the first pipe receiving water from a water main;
a first coupling connecting the first pipe to the water meter housing;
an electrically conductive second pipe in fluid communication with an outlet of the water meter housing, the second pipe providing the water to a building; and
a second coupling connecting the second pipe to the water meter housing,
wherein the first coupling and the second coupling comprise:
an electrically non-conductive nut holding a flared end of each pipe to the water meter housing; and
an electrically non-conductive washer residing between the flared end of each pipe and the water meter housing inlet and outlet and electrically isolate the water meter housing from the first pipe and the second pipe respectively.
